(19) United States
(12) Patent Application Publication
(10) Pub. No.: US 2023/0337484 A1
(43) Pub. Date: Oct. 19, 2023

(54) DISPLAY DEVICE AND METHOD FOR MANUFACTURING DISPLAY DEVICE

(71) Applicant: SHARP KABUSHIKI KAISHA, Sakai City, Osaka (JP)

(72) Inventors: TOHRU OKABE, Sakai City, Osaka (JP); SHOJI OKAZAKI, Sakai City, Osaka (JP); SHINSUKE SAIDA, Sakai City, Osaka (JP); SHINJI ICHIKAWA, Sakai City, Osaka (JP)

(21) Appl. No.: 18/013,532

(22) PCT Filed: Jul. 1, 2020
(86) PCT No.: PCT/JP2020/025747

§ 371 Date: Dec. 28, 2022

(51) Int. Cl. H10K 59/131; H10K 59/124; H10K 77/10; H10K 59/12

(52) U.S. Cl. CPC H10K 59/131; H10K 59/124; H10K 77/111; H10K 59/1201; H10K 2102/311

(57) ABSTRACT

A display device includes a display region of an image, a terminal region provided with a plurality of terminals, a bending region being a region between the display region and the terminal region and being bendable, the bending region includes a first resin layer, a plurality of relay wiring lines provided on the first resin layer and provided between the display region and the terminal region, a second resin layer provided at an upper layer of the plurality of relay wiring lines and the first resin layer, and a third resin layer provided on the second resin layer, and a surface of each of the second resin layer and the third resin layer is provided with a plurality of anchor portions each of which includes a protruding portion provided at one surface and a recessed portion provided at the other surface, the recessed portion being engaged with the protruding portion.

### TECHNICAL FIELD

The disclosure relates to a display device and a manufacturing method of the display device.

### BACKGROUND ART

PTL 1 discloses a display device that is bent near an end portion thereof.

### CITATION LIST

### Patent Literature

PTL 1: JP 2016-170266 A

### SUMMARY OF INVENTION

### Technical Problem

A plurality of resin layers are layered in a bending region of the display device. However, when the region to be bent is bent, the plurality of resin layers may peel off from each other. An aspect of the disclosure is to obtain a display device in which the plurality of resin layers layered in the bending region are difficult to peel off from each other, and a manufacturing method of the display device.

### Solution to Problem

A display device according to an aspect of the disclosure includes a display region of an image, a terminal region provided with a plurality of terminals, and a bending region being a region between the display region and the terminal region and being bendable, the bending region including a first resin layer, a plurality of relay wiring lines provided on the first resin layer and provided between the display region and the terminal region, a second resin layer provided at an upper layer of the plurality of relay wiring lines and the first resin layer, and a third resin layer provided on the second resin layer, and a surface of each of the second resin layer and the third resin layer being provided with a plurality of anchor portions each of which includes a protruding portion provided at one surface and a recessed portion provided at the other surface, the recessed portion being engaged with the protruding portion.

A manufacturing method of a display device according to an aspect of the disclosure, the display device including a display region of an image, a terminal region provided with a plurality of terminals, and a bending region being a region between the display region and the terminal region and being bendable, the manufacturing method including forming the bending region, the forming of the bending region including forming a first resin layer, forming a plurality of relay wiring lines between the display region and the terminal region on the first resin layer, forming a second resin layer at an upper layer of the plurality of relay wiring lines and the first resin layer, forming a plurality of protruding portions or a plurality of recessed portions at a surface of the second resin layer, and forming a third resin layer on the second resin layer, and the forming of the third resin layer including forming a plurality of anchor portions by forming a plurality of recessed portions engaged with the plurality of protruding portions, or a plurality of protruding portions that are to be engaged with the plurality of recessed portions.

### Advantageous Effects of Invention

According to one aspect of the disclosure, the display device in which the plurality of resin layers layered in the bending region are difficult to peel off from each other and the manufacturing method of the display device can be provided.

### BRIEF DESCRIPTION OF DRAWINGS

FIG. 1 is a plan view schematically illustrating a display panel included in a display device according to a first embodiment.

FIG. 2 is a cross-sectional view of the display panel in the display device according to the first embodiment near a subpixel.

FIG. 3 is a schematic cross-sectional view illustrating a state in which the display panel 2 in the display device 1 according to the first embodiment is bent.

FIG. 4 is a plan view illustrating a schematic configuration near both end portions of the bending region of the display panel according to the first embodiment.

FIG. 5 is a cross-sectional view obtained by taking a portion near one of both the end portions of the bending region of the display panel according to the first embodiment along a line B1-B1 illustrated in FIG. 4.

FIG. 6 is a cross-sectional view obtained by taking a portion near one of both the end portions of the bending region of the display panel according to the first embodiment along a line C1-C1 illustrated in FIG. 4.

FIG. 7 is a flowchart illustrating a manufacturing process of the display device according to the first embodiment.

FIG. 8 is a cross-sectional view of a bending region BA according to a first modified example of the first embodiment.

FIG. 9 is a cross-sectional view of the bending region BA according to a second modified example of the first embodiment.

FIG. 10 is a plan view illustrating a schematic configuration near both end portions of a bending region of a display panel according to a third modified example of the first embodiment.

FIG. 11 is a cross-sectional view obtained by taking the display panel according to the third modified example of the first embodiment along a D1-D1 line illustrated in FIG. 10.

FIG. 12 is a cross-sectional view of a display panel in a display device according to a second embodiment near a subpixel.

FIG. 13 is a cross-sectional view obtained by taking a lead-out wiring line at one end near the bending region according to the second embodiment in a Y direction.

FIG. 14 is a cross-sectional view obtained by taking a relay wiring line at one end of the bending region according to the second embodiment in an X direction.

### DESCRIPTION OF EMBODIMENTS

### First Embodiment

A first embodiment of the disclosure will be described below. Note that in the following, “the same layer” means being formed of the same material in the same step.

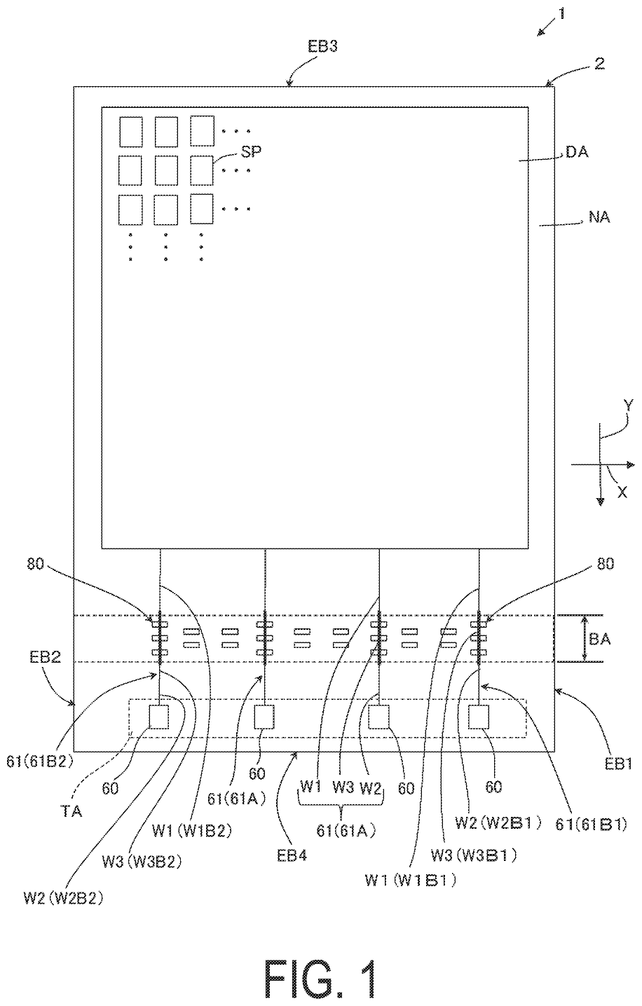

FIG. 1 is a plan view schematically illustrating a display panel 2 included in a display device 1 according to the first embodiment. As illustrated in FIG. 1, the display device 1 according to the present embodiment includes the display panel 2.

The display panel 2 includes a display region DA of an image, and a frame region (non-display region) NA having a frame-like shape surrounding the periphery of the display region DA. Further, the display panel 2 includes a terminal region TA provided in the frame region NA, a plurality of lead-out wiring lines 61, and a bending region BA. In addition, a plurality of anchor portions 80 including a plurality of protruding portions and a plurality of recessed portions are formed in the bending region BA.

The display panel 2 is surrounded by, for example, four end portions EB1, EB2, EB3, and EB4, and has a square shape in a plan view. In the plan view, the end portion EB1 and the end portion EB2 are long sides opposed to each other, and the end portion EB3 and end portion EB4 are short sides opposed to each other. Note that a planar shape of the display panel 2 is not limited to a square, and may have another shape. The display Panel 2 is formed so as to have a desired size by cutting the end portions EB1, EB2, EB3, and EB4 by using a laser or the like in a singulation step after being formed as a panel having a size larger than that of the display panel 2, for example.

Note that in the present embodiment, a direction from the display region DA to the terminal region TA (a direction in which each of the end portions EB1 and EB2 extends, a longitudinal direction from the top toward the bottom of the page in FIG. 1) is defined as a Y direction (first direction), and a direction in which each of the end portions EB3 and EB4 extends (a lateral direction from the left toward the right of the page in FIG. 1) is defined as an X direction (second direction). The Y direction and the X direction are directions orthogonal to each other.

In the display region DA, a plurality of subpixels SP are disposed in a matrix shape. The plurality of subpixels SP include, for example, a red subpixel that emits red light, a green subpixel that emits green light, a blue subpixel that emits blue light, and the like.

The terminal region TA is a region where a plurality of terminals 60 are provided side by side. The terminal region TA is positioned near one end portion EB4 of the display panel 2, and extends along the end portion EB4, for example. The plurality of terminals 60 provided in the terminal region TA are electrically connected to a plurality of terminals, a plurality of wiring lines, or the like, of a circuit provided outside the display panel 2 or the like, which will be described below. The plurality of terminals 60 are positioned, for example, near one end portion EB4 of the display panel 2, and are aligned along the end portion EB4.

The bending region BA is a region between the display region DA and the terminal region TA, and is a region that is bendable. For example, the bending region BA continuously extends so as to connect both the end portions EB1 and EB2 to each other. The bending region BA is provided so as to extend in the X direction. In other words, a longitudinal direction of the bending region BA is the X direction, and a short-hand direction orthogonal to the longitudinal direction is the Y direction.

For example, the display panel 2 includes a flexible base material having flexibility, so that the bending region BA can be bent, for example, by 180°. Note that the display panel 2 does not need to include a flexible base material having flexibility on the entire surface, and may include a flexible base material having flexibility at least in the bending region BA, so that the bending region BA may be bendable.

The plurality of lead-out wiring lines 61 are individually provided between the display region DA and the terminal region TA. The plurality of lead-out wiring lines 61 individually extend from the display region DA to the frame region NA, pass through the bending region BA, and are electrically connected to the plurality of terminals 60 in the terminal region TA. Thus, input signals input to the plurality of terminals 60 from an external circuit of the display panel 2 through the plurality of lead-out wiring lines 61 can be supplied to the display region DA, and output signals output from the display region DA can be supplied to the plurality of terminals 60.

The plurality of lead-out wiring lines 61 extend in the Y direction and are disposed side by side in the X direction. Each of the plurality of lead-out wiring lines 61 includes a first lead-out wiring line W1, a second lead-out wiring line W2, and a relay wiring line W3.

Each of a plurality of first lead-out wiring lines W1 is electrically connected at one end portion to a wiring line, a thin film transistor, or the like provided in the display region DA, and extends in a direction from the display region DA to the bending region BA, and the other end portion is provided in the frame region NA near the bending region BA. Each of a plurality of second lead-out wiring lines W2 is electrically connected at one end portion thereof to the terminal 60, and extends in a direction from the terminal 60 to the bending region BA, and the other end portion thereof is provided in the frame region NA near the bending region BA. The plurality of relay wiring lines W3 are provided between the display region DA and the terminal region TA. Each of the plurality of relay wiring lines W3 is electrically connected at one end portion thereof to the other end portion of the first lead-out wiring line W1, and extends so as to pass through the bending region BA, and the other end portion thereof is electrically connected to the other end portion of the second lead-out wiring line W2. Due to this, the relay wiring line W3 electrically connects the first lead-out wiring line W1 and the second lead-out wiring line W2. Each of the plurality of relay wiring lines W3 extends so as to intersect the longitudinal direction (X direction) of the bending region BA.

Note that, among the plurality of lead-out wiring lines 61 aligned in the Y direction, the lead-out wiring lines 61 at both end portions may be referred to as lead-out wiring lines 61B1 and 61B2. Among the lead-out wiring lines 61 at both end portions, the lead-out wiring line closer to the end portion EB1 is referred to as the lead-out wiring line 61B1, and the lead-out wiring line closer to the end portion EB2 is referred to as the lead-out wiring line 61B2.

Additionally, among the wiring lines included in the lead-out wiring line 61B1, the first lead-out wiring line W1 may be referred to as a first lead-out wiring line W1B1, the second lead-out wiring line W2 may be referred to as a second lead-out wiring line W2B1, and the relay wiring line W3 may be referred to as a relay wiring line W3B1.

Additionally, among the wiring lines included in the lead-out wiring line 61B2, the first lead-out wiring line W1 may be referred to as a first lead-out wiring line W1B1, the second lead-out wiring line W2 may be referred to as a second lead-out wiring line W2B2, and the relay wiring line W3 may be referred to as a relay wiring line W3B2.

The plurality of anchor portions 80 are constituted by, for example, combining protruding portions provided at the surface of one of a plurality of resin layers layered in the bending region BA and recessed portions provided at the surface of the other of the layered resin layers. The plurality of anchor portions 80 are provided in the bending region BA, so that when the bending region BA is bent, the peel-off of the plurality of resin layers layered in the bending region BA from each other can be suppressed. Details of the plurality of anchor portions 80 will be described later.

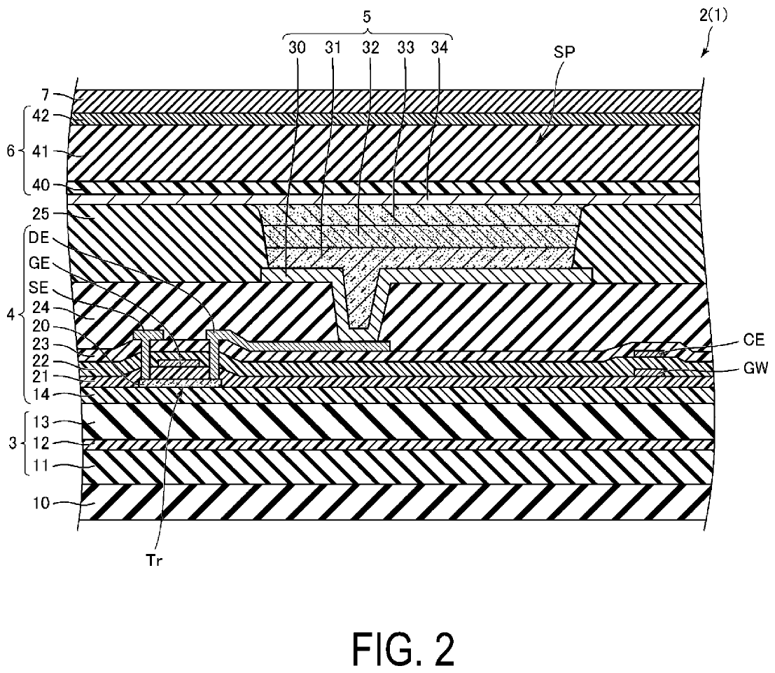

FIG. 2 is a cross-sectional view of the display panel 2 of the display device 1 according to the first embodiment near a subpixel SP. The display panel 2 includes, for example, a second film 10, a base material 3 provided on the second film 10, a base coat layer 14 provided on the base material 3, a thin film transistor (TFT) layer 4 provided on the base coat layer 14, a plurality of light-emitting elements 5 and a bank 25 that are provided on the TFT layer 4, a sealing layer 6 provided on the plurality of light-emitting elements 5 and the bank 25, and a first film 7 provided on the sealing layer 6.

The second film 10 protects the back surface (lower surface) of the display panel 2 and has flexibility. The second film 10 is configured by containing a resin material such as polyethylene terephthalate (PET), for example.

The base material 3 is continuously provided over the entire surface of the display panel 2, and is a member that serves as a base in the display panel 2. The base material 3 has flexibility. In the present embodiment, the base material 3 is a multilayer structure including a first base resin layer 11 provided on the second film 10, a buffer layer 12 provided on the first base resin layer 11, and a second base resin layer 13 provided on the buffer layer 12.

Each of the first base resin layer 11 and the second base resin layer 13 is configured by containing a resin material such as polyimide, for example. For example, the buffer layer 12 is, for example, an inorganic insulating layer configured by containing an inorganic insulating material such as silicon oxide, silicon nitride, or silicon oxynitride.

The first base resin layer 11 and the second base resin layer 13 are members to be provided over the entire surface of the display panel 2 as a base, for example, and do not need to be patterned. That is, the first base resin layer 11 and the second base resin layer 13 do not need to contain a photosensitive material. Thus, the first base resin layer 11 and the second base resin layer 13 have high thermal resistance, compared to a resin layer containing a photosensitive material, and can be cured at a high temperature.

Note that, the base material 3 may have, for example, a single-layer structure constituted by only the first base resin layer 11, or a multilayer structure of four or more layers.

The base coat layer 14 prevents moisture or impurities from entering into the TFT layer 4 and the light-emitting element 5. The base coat layer 14 is an inorganic insulating layer configured by containing an inorganic insulating material such as silicon oxide, silicon nitride, or silicon oxynitride, for example.

The TFT layer 4 includes a semiconductor layer 20, a gate insulating layer 21, a gate electrode GE, a first inorganic insulating layer 22, a capacitance electrode CE, a second inorganic insulating layer 23, a source electrode SE and a drain electrode DE, and a first flattening layer 24. Additionally, the TFT layer 4 includes a gate wiring line GW that is provided at the same layer as that of the gate electrode GE, and further includes a source wiring line (not illustrated) that is provided at the same layer as that of the source electrode SE and the drain electrode DE.

A plurality of thin film transistors Tr for driving the subpixel SP are constituted by the semiconductor layer 20, the gate insulating layer 21, the gate electrode GE, the first inorganic insulating layer 22, the second inorganic insulating layer 23, and the source electrode SE and the drain electrode DE.

The semiconductor layer 20 is formed on the base coat layer 14, and is formed at least in the formation region of the thin film transistor Tr. The semiconductor layer 20 is configured by containing low-temperature polysilicon (LTPS) or an oxide semiconductor, for example. The oxide semiconductor contains at least one metal element selected from In, Ga, and Zn.

The gate insulating layer 21 is provided on the base coat layer 14 so as to cover the semiconductor layer 20. A plurality of gate electrodes GE are provided on the gate insulating layer 21, in the formation regions of the thin film transistors Tr. Further, a plurality of gate wiring lines GW that are provided at the same layer as that of the gate electrodes GE are provided on the gate insulating layer 21. Each of the plurality of gate wiring lines GW is connected to the gate electrode GE.

The first inorganic insulating layer 22 is provided on the gate insulating layer 21 to cover the gate electrodes GE and the gate wiring lines GW. The capacitance electrode CE is provided on the first inorganic insulating layer 22, and overlaps a part of the gate wiring line GW. The capacitance electrode CE forms a capacitance with the overlapping gate wiring line GW. The second inorganic insulating layer 23 covers the capacitance electrode CE, and is provided on the first inorganic insulating layer 22 over the entire surface of the display region DA.

Each of the gate insulating layer 21, the first inorganic insulating layer 22, and the second inorganic insulating layer 23 is configured by containing, for example, an inorganic insulating material such as silicon oxide, silicon nitride, or silicon oxynitride.

The drain electrode DE and the source electrode SE are provided at the same layer, and a plurality of drain electrodes DE and a plurality of source electrodes SE are provided on the second inorganic insulating layer 23 in the formation regions of the thin film transistors Tr. The drain electrode DE is connected to a drain region of the semiconductor layer 20, and the source electrode SE is connected to a source region of the semiconductor layer 20, through contact holes formed in the first inorganic insulating layer 22 and the second inorganic insulating layer 23. Further, a plurality of source wiring lines (not illustrated) are provided at the same layer as that of the drain electrode DE and the source electrode SE on the second inorganic insulating layer 23. Each of the plurality of source wiring lines is connected to the source electrode SE.

The plurality of source wiring lines and the plurality of gate wiring lines GW are provided so as to intersect with each other in the display region DA in a plan view. Each of the plurality of source wiring lines is connected to a source driver (not illustrated), and a source signal corresponding to light emission luminance of each of the plurality of subpixels SP is supplied from the source driver. Each of the plurality of gate wiring lines GW is connected to a gate driver (not illustrated), and a gate signal for selecting a subpixel SP to be emitted from among the plurality of subpixels SP is supplied from the gate driver.

Each of the gate electrode GE, the gate wiring line GW, the capacitance electrode CE, the drain electrode DE, the source electrode SE, and the source wiring line is configured by containing a conductive material. Examples of the conductive material include metal materials such as aluminum, tungsten, molybdenum, tantalum, chromium, titanium, and copper, or an alloy thereof.

The first flattening layer 24 covers the drain electrodes DE, the source electrodes SE, and the source wiring lines, and is provided on the second inorganic insulating layer 23 over the entire display region DA. That is, the first flattening layer 24 covers the plurality of thin film transistors Tr. The first flattening layer 24 is, for example, a resin layer configured by containing a resin material such as polyimide, or acrylic. The first flattening layer 24 contains, for example, a photosensitive material, and is patterned by, for example, a photolithography method or the like.

The plurality of light-emitting elements 5 and the bank 25 are provided on the first flattening layer 24. The plurality of light-emitting elements 5 are individually provided so as to correspond to each subpixel SP. Each of the plurality of light-emitting elements 5 includes, for example, a first electrode 30, a first charge injection layer 31, a light-emitting layer 32, a second charge injection layer 33, and a second electrode 34 that are layered in order on the first flattening layer 24. For example, the first electrode 30, the first charge injection layer 31, the light-emitting layer 32, and the second charge injection layer 33 are provided in an island shape for each light-emitting element 5. For example, the second electrode 34 is provided over the entire surface of the second charge injection layer 33 and the bank 25.

The bank 25 covers a peripheral end portion (edge portion) of the first electrode 30. Thus, the bank 25 prevents a short circuit between the peripheral end portion of the first electrode 30 and the second electrode 34. The bank 25 is provided in a lattice pattern in the display region DA (see FIG. 1) in a plan view. That is, the light-emitting element 5 provided in an opening surrounded by the bank 25 corresponds to the subpixel SP. The bank 25 is, for example, a resin layer configured by containing, for example, a resin material such as polyimide, or acrylic. Also, the bank 25 contains, for example, a photosensitive material, and is patterned by a photolithography method, or the like.

The first electrode 30 is connected to the source electrode SE through a contact hole formed in the first flattening layer 24. The first electrode 30 is, for example, an anode electrode.

The first electrode 30 is, for example, a reflective electrode that reflects visible light. The first electrode 30 is configured as a layered structure of, for example, a reflective layer containing a metal material such as aluminum, copper, gold, or silver having high reflectivity of visible light, and a transparent layer containing ITO, IZO, ZnO, AZO, BZO, GZO, or the like that is a transparent conductive material. Note that the first electrode 30 may have a single-layer structure including a reflective layer.

The second electrode 34 is, for example, a cathode electrode. The second electrode 34 is, for example, a transparent electrode that transmits visible light. The second electrode 34 contains, for example, ITO, IZO, ZnO, AZO, BZO, GZO, or the like that is a transparent conductive material.

The first charge injection layer 31 is provided between the first electrode 30 and the light-emitting layer 32. The first charge injection layer 31 is, for example, a hole injection layer for injecting positive holes into the light-emitting layer 32.

The second charge injection layer 33 is provided between the second electrode 34 and the light-emitting layer 32. The second charge injection layer 33 is, for example, an electron injection layer for injecting electrons into the light-emitting layer 32. Note that another layer such as a hole transport layer may be provided between the first charge injection layer 31 and the light-emitting layer 32. In addition, another layer such as an electron transport layer may be provided between the second charge injection layer 33 and the light-emitting layer 32. Furthermore, at least one of the first charge injection layer 31 and the second charge injection layer 33 may be omitted.

The light-emitting layer 32 is provided between the first electrode 30 and the second electrode 34. In the present embodiment, the light-emitting layer 32 is provided between the first charge injection layer 31 and the second charge injection layer 33. The light-emitting layer 32 emits visible light based on, for example, positive holes injected from the first charge injection layer 31 and electrons injected from the second charge injection layer 33. For example, the light-emitting layer 32 emits red light, green light, or blue light. The light-emitting layer 32 may be, for example, an organic electro-luminescence (EL) layer containing an organic EL material, or a quantum dot layer containing a plurality of quantum dots that emit EL light.

Note that the layering order of the light-emitting element 5 is not limited to the order described above, and for example, the second electrode 34, the second charge injection layer 33, the light-emitting layer 32, the first charge injection layer 31, and the first electrode 30 may be layered in this order on the first flattening layer 24. In addition, for example, the first electrode 30 may be a cathode electrode, the first charge injection layer 31 may be an electron injection layer, the second charge injection layer 33 may be a hole injection layer, and the second electrode 34 may be an anode electrode. Additionally, the first electrode 30 may be a transparent electrode, and the second electrode 34 may be a reflective electrode.

The sealing layer 6 prevents moisture or impurities from entering into the light-emitting element 5. The sealing layer 6 covers the entire surface of the display region DA. The sealing layer 6 includes, for example, an inorganic film 40 provided on the second electrode 34, an organic film 41 provided on the inorganic film 40, and an inorganic film 42 provided on the organic film 41. The inorganic films 40 and 42 are inorganic insulating layers configured by containing an inorganic insulating material such as silicon oxide, silicon nitride, or silicon oxynitride. The organic film 41 is a resin layer configured by containing, for example, a resin material such as polyimide or acrylic.

The first film 7 is provided on the sealing layer 6. The first film 7 protects the front surface (upper surface) of the display panel 2, and has flexibility. The first film 7 is configured by containing, for example, a resin material such as polyethylene terephthalate (PET) resin.

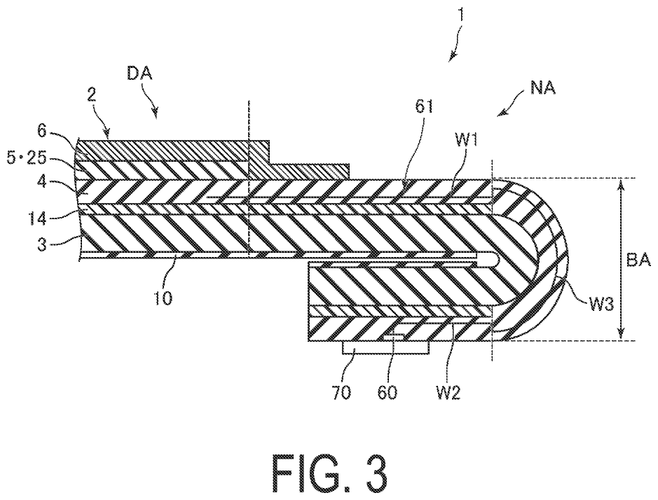

FIG. 3 is a schematic cross-sectional view illustrating a state in which the display panel 2 of the display device 1 according to the first embodiment is bent. Note that, in FIG. 3, illustration of the first film 7 is omitted. As illustrated in FIG. 3, the display device 1 includes a circuit substrate 70 electrically connected to the display panel 2 in addition to the display panel 2. The circuit substrate 70 is, for example, a substrate or the like on which an IC chip is mounted, and is disposed so as to overlap the back surface of the display panel 2. Then, the bending region BA is bendable by 180°, for example, in the display panel 2. In this way, the plurality of terminals 60 in the display panel 2 are individually electrically connected corresponding to the plurality of terminals provided on the circuit substrate 70 provided at the back surface side of the display panel 2. A curvature of bending the bending region BA may be freely-selected and designed, but is approximately equal to or larger than 0.1 mm and equal to or smaller than 1.0 mm, as an example. As a result, the display device 1 subjected to frame narrowing can be implemented.

In addition, in the display device 1 according to the present embodiment, the plurality of anchor portions 80 (FIG. 1) are provided in the bending region BA, and thus, the peel-off of the plurality of resin layers layered in the bending region BA can be suppressed.

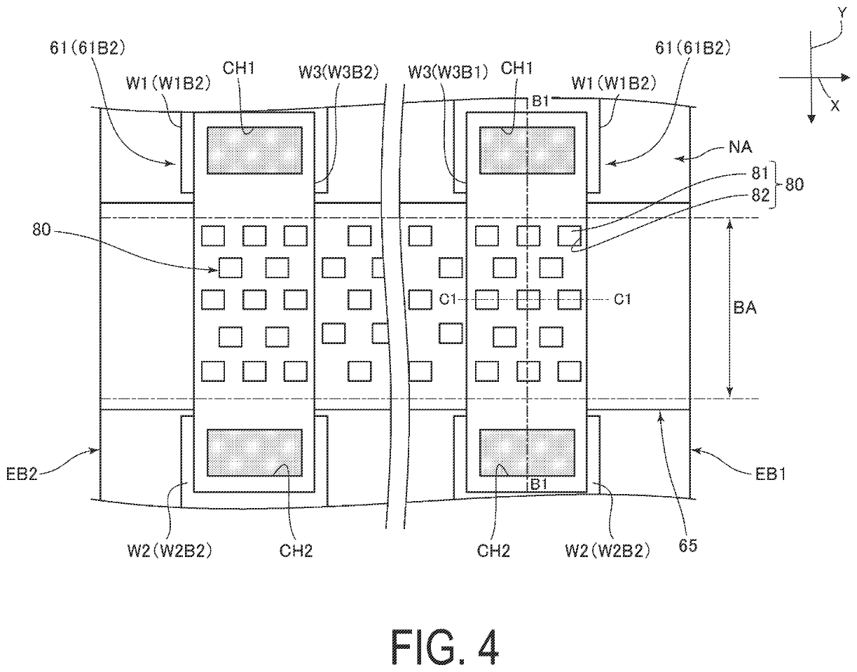

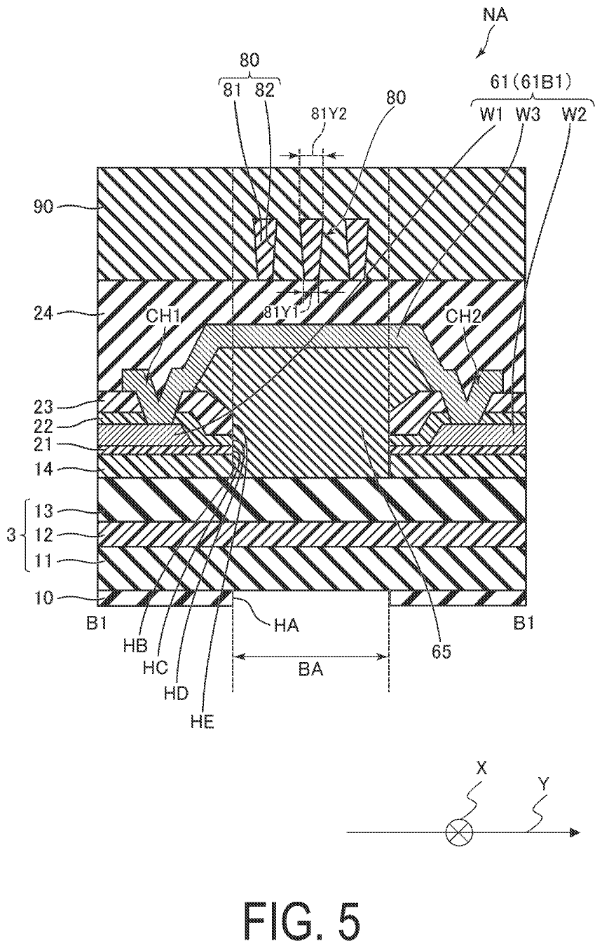

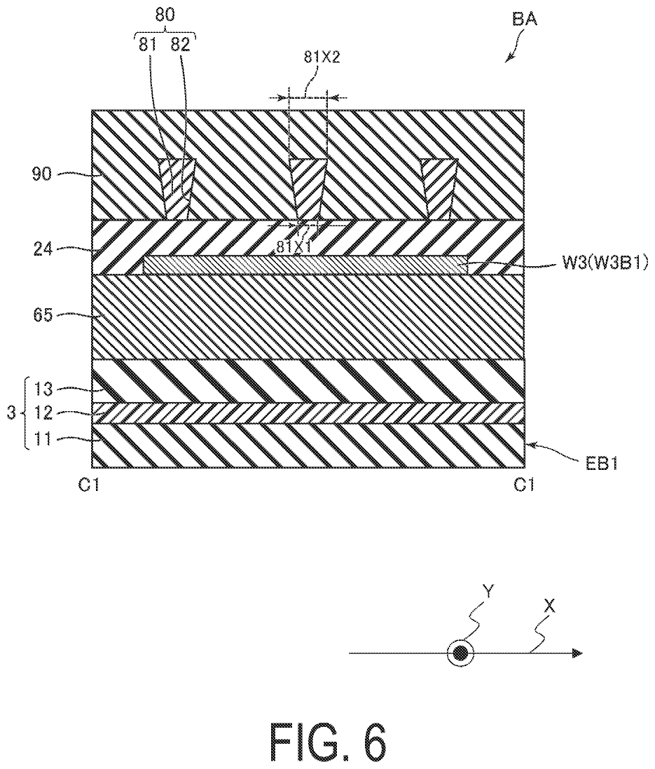

Next, a configuration of the frame region NA near the bending region BA will be described by primarily using FIG. 4 to FIG. 6. FIG. 4 is a plan view illustrating a schematic configuration near both the end portions EB1 and EB2 of the bending region BA of the display panel 2 according to the first embodiment. FIG. 5 is a cross-sectional view obtained by taking a portion near one of both the end portions of the bending region of the display panel according to the first embodiment along a line B1-B1 illustrated in FIG. 4. FIG. 6 is a cross-sectional view obtained by taking a portion near one of both the end portions of the bending region of the display panel according to the first embodiment along a line C1-C1 illustrated in FIG. 4.

For example, among the lead-out wiring lines 61, the first lead-out wiring line W1 and the second lead-out wiring line W2 are provided at the same layer as that of the gate electrode GE, and the relay wiring line W3 is provided at the same layer as that of the drain electrode DE and the source electrode SE.

The relay wiring line W3 is electrically connected at one end portion thereof to an end portion of the first lead-out wiring line W1 through the first contact hole CH1 formed in the first inorganic insulating layer (first insulating layer) 22 and the second inorganic insulating layer (first insulating layer) 23 that cover the first lead-out wiring line W1. Additionally, the other end portion of the relay wiring line W3 is electrically connected to an end portion of the second lead-out wiring line W2 through the second contact hole CH2 formed in the first inorganic insulating layer (first insulating layer) 22 and the second inorganic insulating layer (first insulating layer) 23 that cover the second lead-out wiring line W2.

The base material 3 (that is, the first base resin layer 11, the buffer layer 12, and the second base resin layer 13) provided on the second film 10 is provided in the frame region NA, the base coat layer 14 is provided on the base material 3, the gate insulating layer 21 is provided on the base coat layer 14, and the first lead-out wiring line W1 and the second lead-out wiring line W2 are provided on the gate insulating layer 21. Furthermore, the first inorganic insulating layer 22 is provided on the gate insulating layer 21 so as to cover the first lead-out wiring line W1 and the second lead-out wiring line W2, the second inorganic insulating layer 23 is provided on the first inorganic insulating layer 22, the first flattening layer 24 is provided on the second inorganic insulating layer 23, and a plurality of protruding portions 81 that constitute the plurality of anchor portions 80 and that are provided at the same layer as that of the bank 25 are provided on the first flattening layer 24. Additionally, a reinforcing layer 90 that covers the plurality of protruding portions 81 and that is provided with a plurality of recessed portions 82 constituting the anchor portions 80 is provided on the first flattening layer 24. Furthermore, a filling layer 65 where a plurality of relay wiring lines W3 are layered on a surface thereof is provided in the bending region BA.

In the second film 10, an opening HA is formed in a region overlapping the bending region BA. The base material 3, the first base resin layer 11, the buffer layer 12, and the second base resin layer 13 are provided continuously over the entire surface of the display panel 2 including the bending region BA. The back surface of the first base resin layer 11 is exposed in the bending region BA through the opening HA formed in the second film 10.

In the base coat layer (second insulating layer) 14 provided at the lower layer of the first lead-out wiring line W1 and the second lead-out wiring line W2, an opening HB is formed in a region overlapping the bending region BA. In the gate insulating layer (second insulating layer) 21 provided at the lower layer of the first lead-out wiring line W1 and the second lead-out wiring line W2, an opening HC is formed in the region overlapping the bending region BA. In the first inorganic insulating layer (first insulating layer) 22 provided at the upper layer of the first lead-out wiring line W1 and the second lead-out wiring line W2, an opening HD is formed in the region overlapping the bending region BA. In the second inorganic insulating layer (first insulating layer) 23 provided at the upper layer of the first lead-out wiring line W1 and the second lead-out wiring line W2, an opening HE is formed in the region overlapping the bending region BA.

The surface of the second base resin layer 13 in the bending region BA is exposed through the openings HB to HE.

For example, lengths in the Y direction of the openings HB to HE are substantially the same. Also, for example, the lengths in the Y direction of the openings HB to HE are substantially the same as a length in the Y direction of the opening HA. As an example, the length in the Y direction of the bending region BA is substantially the same as the lengths in the Y direction of the openings HA to HE. Also, the openings HA to HE continuously extend in the X direction so as to connect both the end portions EB1 and EB2 to each other. That is, in the bending region BA, the openings HA to HE extend in a direction intersecting the plurality of relay wiring lines W3.

For example, a length in the Y direction between the end portion of the first lead-out wiring line W1 (the end portion at the side closer to the bending region BA) and the end portion of the second lead-out wiring line W2 (the end portion at the side closer to the bending region BA) is longer than the lengths in the Y direction of the openings HB to HE. In other words, each of the end portion of the first lead-out wiring line W1 (the end portion at the side closer to the bending region BA) and the end portion of the second lead-out wiring line W2 (the end portion at the side closer to the bending region BA) is covered with the first inorganic insulating layer 22 and the second inorganic insulating layer 23.

The filling layer 65 is provided in a region surrounded by the surface of the second base resin layer 13 exposed in the bending region BA, the opening HB formed in the base coat layer 14, the opening HC formed in the gate insulating layer 21, the opening HD formed in the first inorganic insulating layer 22, and the opening HE formed in the second inorganic insulating layer 23. The filling layer 65 continuously extends in the X direction so as to connect both the end portions EB1 and EB2 to each other.

The filling layer 65 is a resin layer configured by containing, for example, a resin material such as polyimide or acrylic. Furthermore, the filling layer 65 contains a photosensitive material to be patterned by a photolithography method, or the like, for example. The relay wiring line W3 extending in the Y direction is provided on the filling layer 65.

The first flattening layer 24 is provided on the filling layer 65 and the second inorganic insulating layer 23 so as to cover the relay wiring line W3.

The plurality of protruding portions 81 constitute the plurality of anchor portions 80, and are provided at the surface of the first flattening layer 24 in the bending region BA. The plurality of protruding portions 81 are, for example, a resin layer configured by containing a resin material such as polyimide, or acrylic. The plurality of protruding portions 81 contain a photosensitive material to be patterned with the bank 25 (FIG. 2) in the same step by a photolithography method, or the like, for example. That is, the plurality of protruding portions 81 are provided at the same layer as that of the bank 25.

The reinforcing layer 90 is provided in the bending region BA in order to reinforce the bending region BA. The reinforcing layer 90 covers the plurality of protruding portions 81 provided in the bending region BA, and is provided on the surface of the first flattening layer 24. In the reinforcing layer 90, the plurality of recessed portions 82 covering the plurality of protruding portions 81 constitute the anchor portions 80.

The reinforcing layer 90 is a resin layer configured by containing, for example, a resin material such as polyimide, or acrylic. The reinforcing layer 90 contains a photosensitive material to be patterned by a photolithography method, or the like, for example. For example, the reinforcing layer 90 is formed in the bending region BA after the light-emitting element 5 (FIG. 2) in the display region DA is formed.

In this way, for example, it is preferable that layers (the base coat layer 14, the gate insulating layer 21, the first inorganic insulating layer 22, and the second inorganic insulating layer 23) formed by using inorganic insulating materials that have lower bending resistance than that of the resin layers be not formed except for the buffer layer 12 included in the base material 3 in the bending region BA.

Next, details of the plurality of anchor portions 80 formed in the bending region BA will be described. As illustrated in FIG. 5 and FIG. 6, as described above, the filling layer (first resin layer) 65, the first flattening layer (second resin layer) 24 provided at the upper layer of the filling layer 65 and the plurality of relay wiring lines W3, and the reinforcing layer (third resin layer) 90 provided on the first flattening layer (second resin layer) 24 are provided in the bending region BA. In other words, the plurality of resin layers are layered in the bending region BA. As an example, in the present embodiment, a layered structure in which three resin layers are layered in the bending region BA is formed.

Then, as illustrated in FIG. 3, the bending region BA of the display panel 2 is bendable by 180°, for example. Thus, in the bending region, the layered plurality of resin layers may peel off from each other. When the layered plurality of resin layers peel off from each other, the stress center when the bending region is bent deviates, and the plurality of resin layers layered in the bending region may have cracks. In addition, when the plurality of resin layers have the cracks in the bending region, the plurality of relay wiring lines provided in the bending region may be disconnected.

Thus, as illustrated in FIG. 5 and FIG. 6, in the bending region BA of the display panel 2 according to the present embodiment, the first flattening layer (second resin layer) 24 and the reinforcing layer (third resin layer) 90 are provided at the respective surfaces thereof with the plurality of anchor portions 80 each of which includes a protruding portion 81 provided at one surface and a recessed portion 82 that is provided at the other surface and that covers the surface of the protruding portion 81. The inner wall surface of the recessed portion 82 and the surface of the protruding portion 81 are in contact with each other, and are engaged with each other. Further, for example, the protruding portion 81 and the recessed portion 82 have shapes that are fitted to each other.

In this way, when the bending region BA is bent, the plurality of protruding portions 81 engaged within the plurality of recessed portions 82 are subjected to stress from the plurality of recessed portions 82 along with bending of the bending region BA, and the plurality of anchor portions 80 exhibit a so-called anchoring effect. Thus, even when the bending region BA is bent, the plurality of protruding portions 81 and the plurality of recessed portions 82 are difficult to be peeled off. That is, the first flattening layer 24 and the reinforcing layer 90 that are the plurality of resin layers layered in the bending region BA of the display panel 2 and that are provided with the plurality of anchor portions 80 can be difficult to be peeled off. This makes it possible to suppress cracks of the first flattening layer 24 and the reinforcing layer 90, and disconnection of the plurality of relay wiring lines W3 provided in the bending region BA due to the cracks.

For example, the plurality of protruding portions 81 of the plurality of anchor portions 80 are provided at the surface of the first flattening layer 24 (one surface). Additionally, among the plurality of anchor portions 80, the plurality of recessed portions 82 are provided at the surface of the reinforcing layer 90 (the other surface).

Here, for example, the reinforcing layer 90 is formed in the bending region BA after the light-emitting element 5 (FIG. 2) in the display region DA is formed. Thus, for example, the reinforcing layer 90 is cured due to heat at a relatively low temperature (for example, approximately 80° C.) so that heat is not applied to the light-emitting element 5 (FIG. 2) at a high temperature. As a result, the reinforcing layer at which the anchor portions are not provided is likely to become poor in adhesion with the resin layer provided at the lower layer of the reinforcing layer, and when the bending region is bent, the reinforcing layer easily peels off from the resin layer provided at the lower layer.

Thus, for example, the plurality of anchor portions 80 are preferably provided at the surface of the reinforcing layer 90 and the surface of the first flattening layer 24 that is in contact with the surface of the reinforcing layer 90. In other words, it is preferable that either the plurality of protruding portions 81 or the plurality of recessed portions 82 be provided at the surface of the reinforcing layer 90, and the other portions of the plurality of protruding portions 81 and the plurality of recessed portions 82 be provided at the surface of the first flattening layer 24 that comes into contact with the surface of the reinforcing layer 90. This allows the peel-off of the reinforcing layer 90 from the first flattening layer 24 to be suppressed in the bending region BA.

Note that the layered plurality of resin layers in which the plurality of anchor portions 80 are provided are not limited to the reinforcing layer 90 and the first flattening layer 24. It is only required that among the plurality of resin layers layered in the bending region BA, the surface of one resin layer is provided with either the plurality of protruding portions 81 or the plurality of recessed portions 82, and the surface of the other resin layer (the surface that contacts the surface of the one resin layer) is provided with the other of the plurality of protruding portions 81 and the plurality of recessed portions 82.

For example, in the bending region BA, another resin layer that has a single layer structure or a multilayer structure is provided on the first flattening layer 24, and the plurality of anchor portions 80 may be provided on the surfaces of the other resin layer and the reinforcing layer 90 that come into contact with each other. Alternatively, when the other resin layer has a multilayer structure, the plurality of anchor portions 80 may be provided at the surfaces of any two resin layers that are in contact with each other. Note that when the other resin layer is provided, the first flattening layer 24 in the bending region BA may be omitted.

As illustrated in FIG. 4, for example, the plurality of anchor portions 80 are provided in a matrix shape in the bending region BA in a plan view. As a result, the reinforcing layer 90 and the first flattening layer 24 in the bending region BA can be less likely to peel off from each other, compared to a case where only one anchor portion is provided in the bending region.

Further, for example, it is preferable that the plurality of anchor portions 80 be provided at inner sides than the relay wiring lines W3B1 and W2B2 provided at both ends among the plurality of relay wiring lines W3 in a plan view. Thus, in the bending region BA, the peel-off of the reinforcing layer 90 and the first flattening layer 24 between the relay wiring lines W3B1 and W2B2 provided at the both ends can be more reliably suppressed. Thereby, cracks in the reinforcing layer 90 and the first flattening layer 24 and disconnection of the plurality of relay wiring lines W3 due to the cracks can be more reliably suppressed.

Note that the plurality of anchor portions 80 may be provided in a region overlapping the relay wiring lines W3B1 and W3B2 positioned at the both ends in a plan view. Also, the plurality of anchor portions 80 may be provided in a region overlapping at least any one of the plurality of relay wiring lines W3 in a plan view.

Further, the plurality of anchor portions 80 may be provided at an outer side than the relay wiring lines W3B1 and W3B2 positioned at the both ends in a plan view. That is, the plurality of anchor portions 80 may be provided at least one of between the relay wiring line W3B1 and the end portion EB1, and between the relay wiring line W3B2 and the end portion EB2.

This makes it possible to more reliably suppress the peel-off of the reinforcing layer 90 and the first flattening layer 24 in a wider range in the bending region BA.

Additionally, as illustrated in FIG. 5 and FIG. 6, for example, the protruding portion 81 may have a reversely tapered shape in which a length in a width direction parallel to the surface of the first flattening layer 24 increases from a base portion that comes into contact with the surface (one surface) of the first flattening layer 24 to a tip portion that is an end portion at an opposite side to the base portion. For example, as illustrated in FIG. 5, the protruding portion 81 may have a shape in which a length 81Y2 in the Y direction of the tip portion is longer than a length 81Y1 in the Y direction of the base portion that comes into contact with the surface (one surface) of the first flattening layer 24. Additionally, the recessed portion 82 has a shape corresponding to the protruding portion 81, and may have a shape that gradually widens in the Y direction from a side closer to the first flattening layer 24 to the farther side. This makes it further difficult for the protruding portion 81 and the recessed portion 82 into which the protruding portion 81 has been inserted to peel off from each other. That is, the first flattening layer 24 and the reinforcing layer 90 are less likely to be peeled off.

Note that the protruding portion 81 may have a so-called tapered shape whose length gradually decreases from the length 81Y1 in the Y direction of the base portion to the length 81Y2 in the Y direction of the tip portion. Also, the recessed portion 82 may have a shape corresponding to that of the protruding portion 81, and may have a shape whose width in the Y direction gradually narrows from the side closer to the first flattening layer 24 to the farther side. Additionally, cross-sectional shapes of the protruding portion 81 and the recessed portion 82 taken along the Y direction are not limited to the tapered shape and the reversely tapered shape, and may be other shapes.

Additionally, as illustrated in FIG. 6, the protruding portion 81 may have a shape in which a length 81X2 in the X direction of the tip portion is longer than a length 81X1 in the X direction of the base portion that comes into contact with the surface (one surface) of the first flattening layer 24. Additionally, the recessed portion 82 has a shape corresponding to that of the protruding portion 81, and may have a shape whose width in the X direction gradually widens from the side closer to the first flattening layer 24 to the farther side. This makes it further difficult for the protruding portion 81 and the recessed portion 82 into which the protruding portion 81 has been inserted to peel off from each other. That is, it makes it possible to hardly peel off the first flattening layer 24 and the reinforcing layer 90 from each other.

Note that the protruding portion 81 may be a so-called tapered shape whose length gradually decreases from the length 81X1 in the X direction of the base portion to the length 81X2 in the X direction of the tip portion. Additionally, the recessed portion 82 has a shape corresponding to that of the protruding portion 81, and may have a shape whose width gradually narrows in the X direction from the side closer to the first flattening layer 24 to the farther side. In addition, the cross-sectional shapes of the protruding portion 81 and the recessed portion 82 taken along the X direction are not limited to the tapered shape and the reversely tapered shape, and may be other shapes.

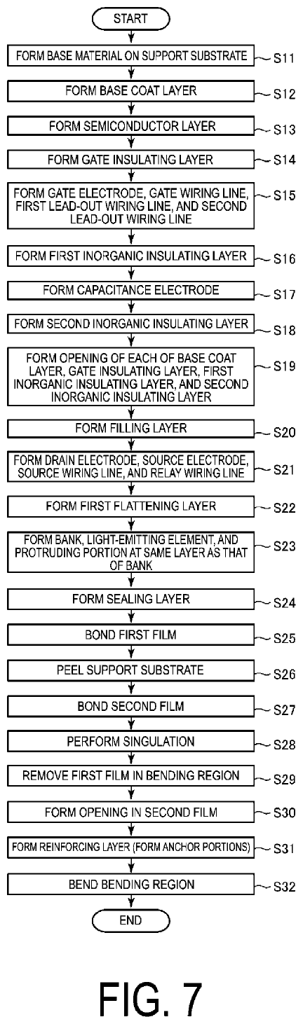

Next, a manufacturing method of the display device 1 will be described. FIG. 7 is a flowchart illustrating a manufacturing process of the display device 1 according to the first embodiment.

First, the base material 3 is formed on a support substrate having transparency (for example, mother glass) (step S11). That is, the first base resin layer 11 is formed by applying and heating a resin material such as polyimide on a surface of the support substrate. Next, the buffer layer 12 is formed on the surface of the first base resin layer 11 by a CVD method, or the like, using an inorganic insulating material such as silicon oxide, silicon nitride, or silicon oxynitride. Next, a resin material such as polyimide is applied and heated to form the second base resin layer 13 on the surface of the buffer layer 12. The first base resin layer 11 and the second base resin layer 13 do not contain a photosensitive material, and are formed by, for example, heating at a relatively high temperature of approximately 500° C.

Next, the base coat layer 14 is formed on the surface of the base material 3 by a CVD method or the like using an inorganic insulating material such as silicon oxide, silicon nitride, or silicon oxynitride (step S12). Next, the semiconductor layer 20 is formed by using polysilicon, an oxide semiconductor material, or the like in the formation region of the thin film transistor Tr (step S13).

Next, the gate insulating layer 21 is formed on the surface of the base coat layer 14 so as to cover the semiconductor layer 20 by a CVD method or the like using an inorganic insulating material such as silicon oxide, silicon nitride, or silicon oxynitride (step S14). Next, a metal material such as aluminum, tungsten, molybdenum, tantalum, chromium, titanium, or copper, or an alloy thereof is formed on the surface of the gate insulating layer 21 by a sputtering method or the like, and the gate electrode GE, the gate wiring line GW, the first lead-out wiring line W1, and the second lead-out wiring line W2 are formed by a photolithography method (step S15). In this manner, the gate electrode GE, the gate wiring line GW, the first lead-out wiring line W1, and the second lead-out wiring line W2 are formed by using the same material in the same step, that is, at the same layer.

Next, the first inorganic insulating layer 22 is formed on the surface of the gate insulating layer 21 so as to cover the gate electrode GE, the gate wiring line GW, the first lead-out wiring line W1, and the second lead-out wiring line W2, by a CVD method or the like using an inorganic insulating material such as silicon oxide, silicon nitride, or silicon oxynitride (step S16). Next, a metal material such as aluminum, tungsten, molybdenum, tantalum, chromium, titanium, or copper, or an alloy thereof is film-formed on the surface of the first inorganic insulating layer 22 by a sputtering method or the like, and the capacitance electrode CE is formed by a photolithography method (step S17). Next, the second inorganic insulating layer 23 is formed on the surface of the first inorganic insulating layer 22 so as to cover the capacitance electrode CE by a CVD method or the like using an inorganic insulating material such as silicon oxide, silicon nitride, or silicon oxynitride (step S18).

Next, the second inorganic insulating layer 23, the first inorganic insulating layer 22, the gate insulating layer 21, and the base coat layer 14 in the bending region BA are removed by etching, and thus, the openings HB to HE are collectively formed (step S19). This exposes the surface of the second base resin layer 13 in the bending region BA.

Next, the filling layer 65 is formed in the region surrounded by the openings HB to HE on the exposed surface of the second base resin layer 13 in the bending region BA by a photolithography method or the like using a resin material such as polyimide, or acrylic (step S20).

Next, a metal material such as aluminum, tungsten, molybdenum, tantalum, chromium, titanium, or copper, or an alloy thereof is film-formed on the surface of the second inorganic insulating layer 23 by a sputtering method or the like, and the drain electrode DE, the source electrode SE, and the source wiring line are formed by a photolithography method and the relay wiring line W3 is formed at the surface of the filling layer 65, at the same layer as each other (step S21). This forms the plurality of relay wiring lines W3 between the display region DA and the terminal region TA. In this manner, the drain electrode DE, the source electrode SE, the source wiring line, and the relay wiring line W3 are formed by using the same material in the same step, that is, at the same layer.

Here, in the display region DA, the drain electrode DE is connected to the drain region of the semiconductor layer 20 and the source electrode SE is connected to the source region of the semiconductor layer 20, through a contact hole formed so as to penetrate through the first inorganic insulating layer 22 and the second inorganic insulating layer 23 in advance. Thus, the thin film transistors Tr are formed in the display region DA.

In addition, near the bending region BA, one end portion of the relay wiring line W3 is connected to one end portion of the first lead-out wiring line W1 through the first contact hole CH1 formed so as to penetrate through the first inorganic insulating layer 22 and the second inorganic insulating layer 23 in advance, and the other end portion of the relay wiring line W3 is connected to one end portion of the second lead-out wiring line W2 through the second contact hole CH2. The plurality of relay wiring lines W3 are aligned and formed at the surface of the filling layer 65 in a direction in which the bending region BA extends. Due to this, the plurality of relay wiring lines W3 electrically connect the display region DA and the terminal region TA through the bending region BA. As a result, a plurality of lead-out wiring lines 61 are formed in the frame region NA.

Next, the first flattening layer 24 is formed on the surface of the second inorganic insulating layer 23 and the surface of the filling layer 65 so as to cover the thin film transistor Tr and the relay wiring line W3 by a photolithography method or the like using a resin material such as polyimide, or acrylic (step S22).

Next, the first electrode 30, the bank 25, the light-emitting element 5, and the plurality of protruding portions 81 provided at the same layer as that of the bank 25 in the bending region BA are formed at the surface of the first flattening layer 24 (step S23).

That is, for example, each of a reflective layer containing a metal material such as aluminum, copper, gold, or silver, and a transparent layer containing ITO, IZO, ZnO, AZO, BZO, GZO, or the like is formed to be patterned on the surface of the first flattening layer 24 by a photolithography method, thereby forming the first electrode 30 in the formation region of the light-emitting element 5. In this way, the first electrode 30 is connected to the drain electrode DE through the contact hole formed so as to penetrate through the first flattening layer 24 in advance.

In addition, in the display region DA, the bank 25 is formed in a lattice pattern on the surface of the first flattening layer 24 so as to cover a peripheral end portion (edge portion) of the first electrode 30 by a photolithography method or the like using a resin material such as polyimide or acrylic. In addition, in the bending region BA, a resin layer is film-formed and patterned on the surface of the first flattening layer 24 by using the same material in the same step as those of the bank 25 (that is, at the same layer), thereby forming the plurality of protruding portions 81.

Then, in the display region DA, the first charge injection layer 31, the light-emitting layer 32, and the second charge injection layer 33 are formed in order, by a vapor deposition method, or the like, in the region surrounded by the bank 25 on the first electrode 30. Then, the second electrode 34 is formed on the surface of the bank 25 and the surface of the second charge injection layer 33 by a vapor deposition method, or the like, using a transparent conductive material such as ITO, IZO, ZnO, AZO, BZO, or GZO. Thereby, the plurality of light-emitting elements 5 are formed in the display region DA.

Next, the sealing layer 6 is formed (step S24). That is, the inorganic film 40, the organic film 41, and the inorganic film 42 are sequentially layered on the surfaces of the second electrode 34 and the first flattening layer 24. The inorganic films 40 and 42 are formed by using an inorganic insulating material such as silicon oxide, silicon nitride, or silicon oxynitride, for example, by a CVD method, or the like. The organic film 41 is formed by using a resin material such as polyimide, or acrylic by an ink-jet method or the like.

Next, the first film 7 containing a resin material such as polyethylene terephthalate (PET) is bonded to the surface of the sealing layer 6 (step S25). Next, the first base resin layer 11 is irradiated with, for example, a laser from the back surface side of the support substrate through the support substrate to peel the support substrate off from the back surface of the first base resin layer 11 (step S26). Next, the second film 10 containing a resin material such as polyethylene terephthalate (PET) is bonded to the back surface of the first base resin layer 11 with the support substrate peeled off (step S27).

Next, the end portions EB1 to EB4 that are outer edges of the display panel 2 are cut with a laser or the like so that the display panel 2 has a desired size. Thus, the display panel 2 is singulated to a desired size (step S28).

Next, the region of the first film 7 that overlaps the bending region BA and the region of the first film 7 that overlaps the terminal region are removed (step S29). Next, the opening HA is formed in a region of the second film 10 that overlaps the bending region BA (step S30).

Next, a resin material such as polyimide, or acrylic is applied to the bending region BA and the terminal region TA, and is cured to form the reinforcing layer 90 that covers the surface of the first flattening layer 24 on the first flattening layer 24 (step S31). The reinforcing layer 90 is formed, thereby forming the plurality of recessed portions 82 that are engaged with the plurality of protruding portions 81 exposed in the bending region BA at a surface of the reinforcing layer 90 that comes into contact with the first flattening layer 24. In other words, the reinforcing layer 90 formed with the plurality of recessed portions 82 that cover the surfaces of the plurality of protruding portions 81 is formed on the surface of the first flattening layer 24. That is, the plurality of anchor portions 80 constituted by the plurality of protruding portions 81 and the plurality of recessed portions 82 that are engaged with the plurality of protruding portions 81 are formed in the bending region BA.

The reinforcing layer 90 contains, for example, ultraviolet-curing resin, and is cured by irradiation with ultraviolet light. Further, for example, by applying heat having a relatively low temperature of about 80°, the reinforcing layer 90 is further cured.

Next, the bending region BA of the singulated display panel 2 is bent, for example, by 1800 (step S32). Here, the plurality of anchor portions 80 are formed in the bending region BA, and thus, even when the bending region BA is bent, the first flattening layer 24 and the reinforcing layer 90 that are provided with the plurality of anchor portions 80 are difficult to peel off from each other. Thus, generation of cracks in the first flattening layer 24 and the reinforcing layer 90, and disconnection of the plurality of relay wiring lines W3 provided in the bending region BA due to the cracks are suppressed. In addition, after that, the plurality of terminals 60 in the terminal region TA are electrically connected to the corresponding plurality of terminals provided on the circuit substrate 70 provided at the back surface side of the display panel 2. This completes the display device 1.

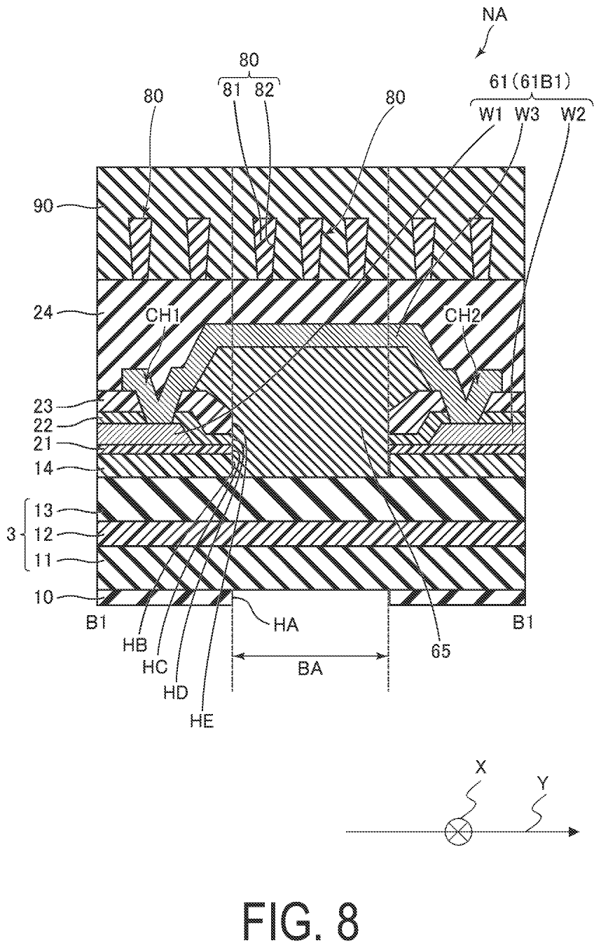

FIG. 8 is a cross-sectional view of the bending region BA according to a first modified example of the first embodiment. A planar shape of the display panel 2 according to the first modified example is the same as that in FIG. 4. The reinforcing layer 90 may be provided only in a region overlapping the bending region BA on the first flattening layer, and may be provided in a region including the bending region BA and being wider than the bending region BA. The plurality of anchor portions 80 may be provided only in the bending region BA, or may be provided outside the bending region BA in addition to being provided in the bending region BA.

This makes it possible to improve adhesion between the reinforcing layer 90 and the first flattening layer 24. Thus, the reinforcing layer 90 and the first flattening layer 24 can further be suppressed from peeling off when the bending region BA is bent.

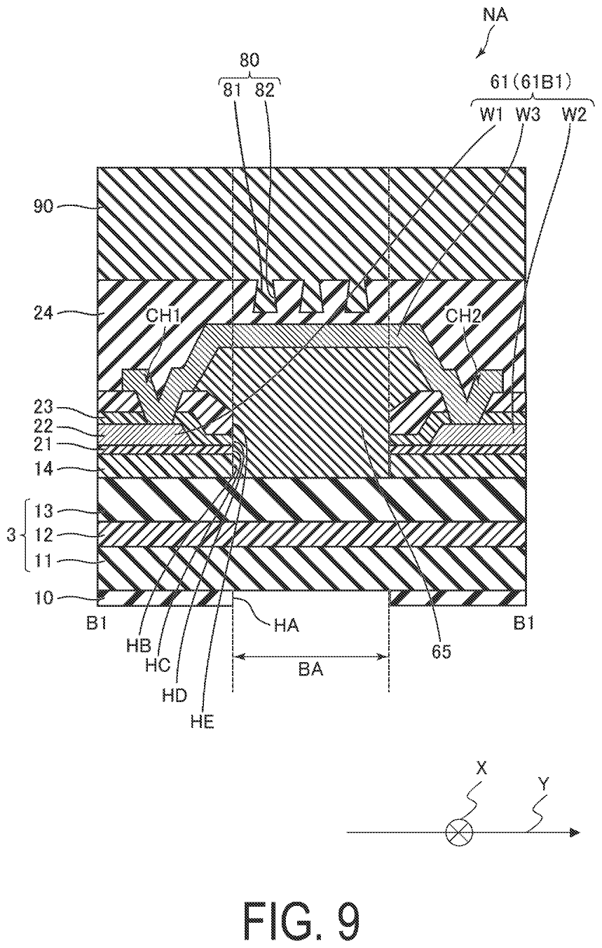

FIG. 9 is a cross-sectional view of the bending region BA according to a second modified example of the first embodiment. The planar shape of the display panel 2 according to the second modified example is the same as that in FIG. 4.

As illustrated in FIG. 9, the plurality of protruding portions 81 may be provided on the surface (one surface) of the reinforcing layer 90, and the plurality of recessed portions 82 may be provided on the surface (the other surface) of the first flattening layer 24. The surfaces of the plurality of protruding portions 81 are covered with the plurality of recessed portions 82. In the example illustrated in FIG. 9, the plurality of protruding portions 81 are parts of the reinforcing layer 90. These also constitute the anchor portions 80. In the example of the anchor portions 80 illustrated in FIG. 9, prior to forming the plurality of protruding portions 81, the plurality of recessed portions 82 are formed at the surface of the first flattening layer 24, and then the reinforcing layer 90 including the plurality of protruding portions 81 is formed such that the surfaces thereof are covered by the plurality of recessed portions 82. In this way, the anchor portions 80 including the recessed portions 82 and the protruding portions 81 that have shapes being fitted to each other are formed. Note that the plurality of protruding portions 81 may be provided at the same layer as another resin layer (for example, the bank 25), rather than the parts of the reinforcing layer 90.

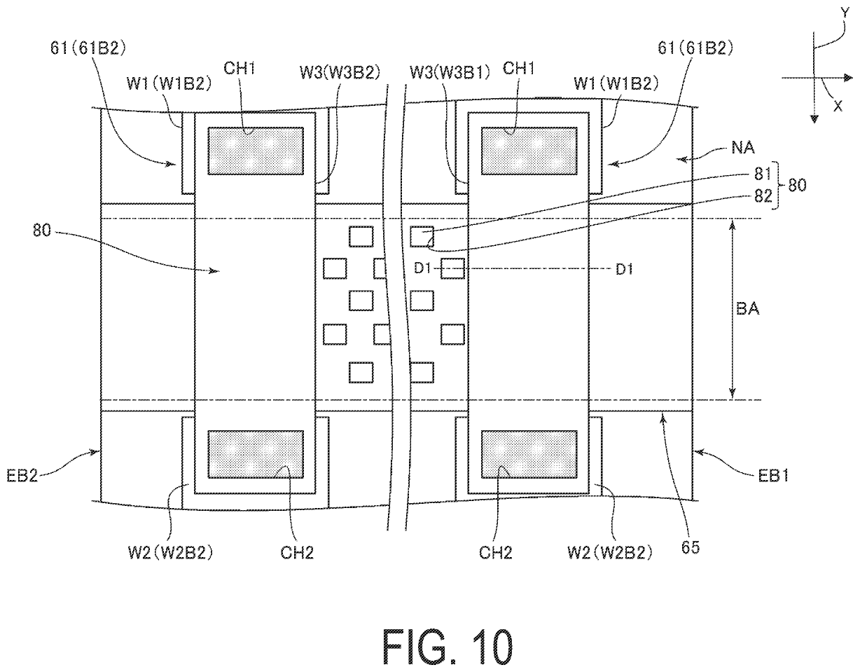

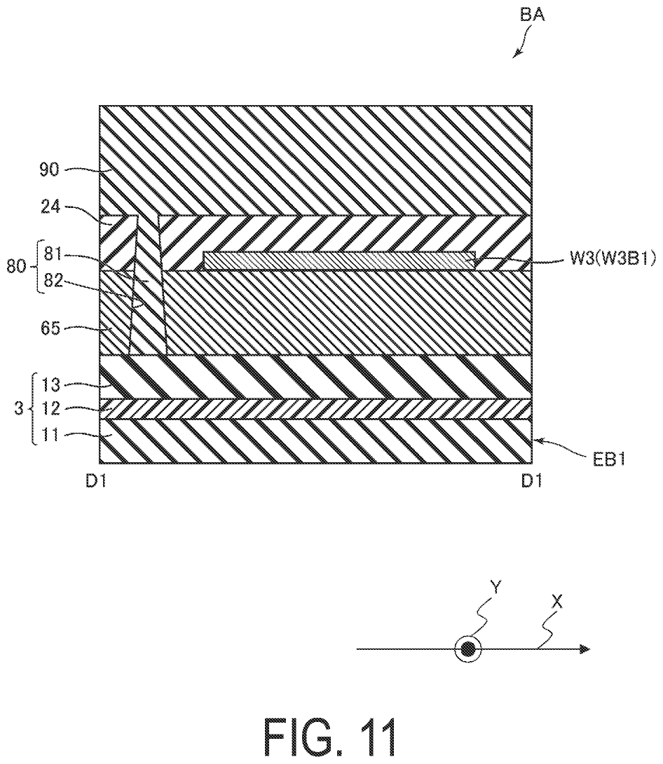

FIG. 10 is a plan view illustrating a schematic configuration near both the end portions EB1 and EB2 of the bending region BA of the display panel 2 according to a third modified example of the first embodiment. FIG. 11 is a cross-sectional view of the display panel 2 according to the third modified example of the first embodiment taken along a D1-D1 line illustrated in FIG. 10.

As illustrated in FIG. 10 and FIG. 11, in a plan view, the anchor portions 80 may be provided so as not to overlap the corresponding plurality of relay wiring lines W3. Furthermore, when the plurality of protruding portions 81 are provided at the surface (one surface) of the reinforcing layer 90, and the plurality of recessed portions 82 are provided at the surface (the other surface) of the first flattening layer 24, at least one of the plurality of recessed portions 82 may have a depth where the at least one recessed portion penetrates through the first flattening layer (second resin layer) 24 and the filling layer (first resin layer) 65. Then, for example, some of the plurality of protruding portions 81 that are parts of the reinforcing layer 90 may be inserted into the recessed portions 82 so as to penetrate through the first flattening layer (second resin layer) 24 and the filling layer (first resin layer) 65. This can further enhance the anchoring effect. As a result, when the bending region BA is bent, the reinforcing layer 90 can be more reliably suppressed from peeling off from the first flattening layer 24.

### Second Embodiment

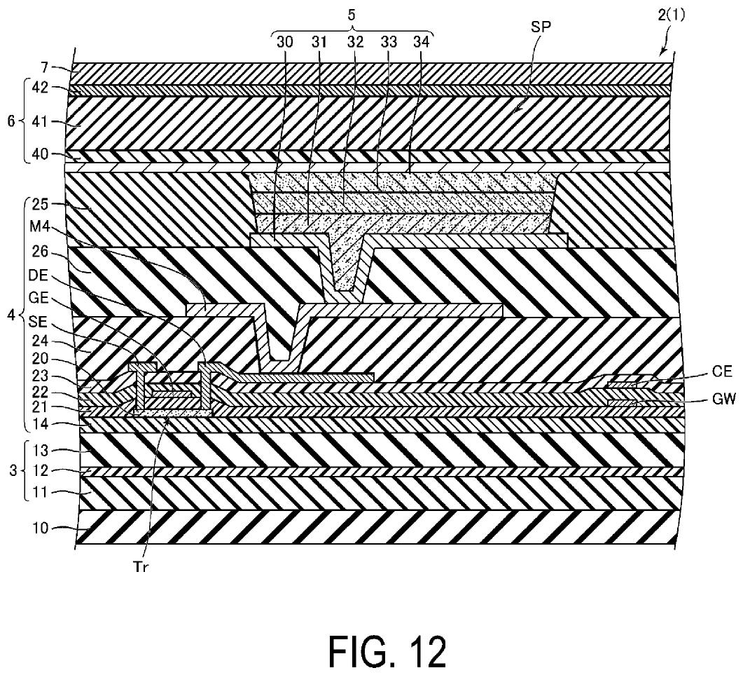

A second embodiment of the disclosure will be described below. Note that a difference from the first embodiment will be mainly described, and a description of contents overlapping the first embodiment will be omitted. FIG. 12 is a cross-sectional view of the display panel 2 of the display device 1 according to the second embodiment near the subpixel SP. Note that a planar shape of the display panel 2 of the display device 1 according to the second embodiment is similar to that in FIG. 1.

As illustrated in FIG. 12, the TFT layer 4 in the display panel 2 may further include an intermediate electrode M4 and a second flattening layer 26.

The intermediate electrode M4 is provided in an island shape on the first flattening layer 24, and is electrically connected to the drain electrode DE through a contact hole formed in the first flattening layer 24. The intermediate electrode M4 electrically connects the drain electrode DE and the first electrode 30. In addition, a wiring line such as a lead-out wiring line is provided at the same layer as that of the intermediate electrode M4 in the frame region NA. The intermediate electrode M4 and the wiring line provided at the same layer as that of the intermediate electrode M4 are configured by containing a conductive material. Examples of the conductive material include metal materials such as aluminum, tungsten, molybdenum, tantalum, chromium, titanium, and copper, or an alloy thereof.

The second flattening layer 26 covers the intermediate electrode M4, and is provided over the entire surface of the display region DA on the first flattening layer 24. The second flattening layer 26 is, for example, a resin layer configured by containing a resin material such as polyimide, or acrylic. The second flattening layer 26 is, for example, patterned by containing a photosensitive material, for example, by a photolithography method, or the like.

The plurality of light-emitting elements 5 and the bank 25 are provided on the second flattening layer 26 in the present embodiment. The first electrode 30 is connected to the intermediate electrode M4 through a contact hole formed in the second flattening layer 26. That is, the first electrode 30 is electrically connected to the drain electrode DE through the intermediate electrode M4.

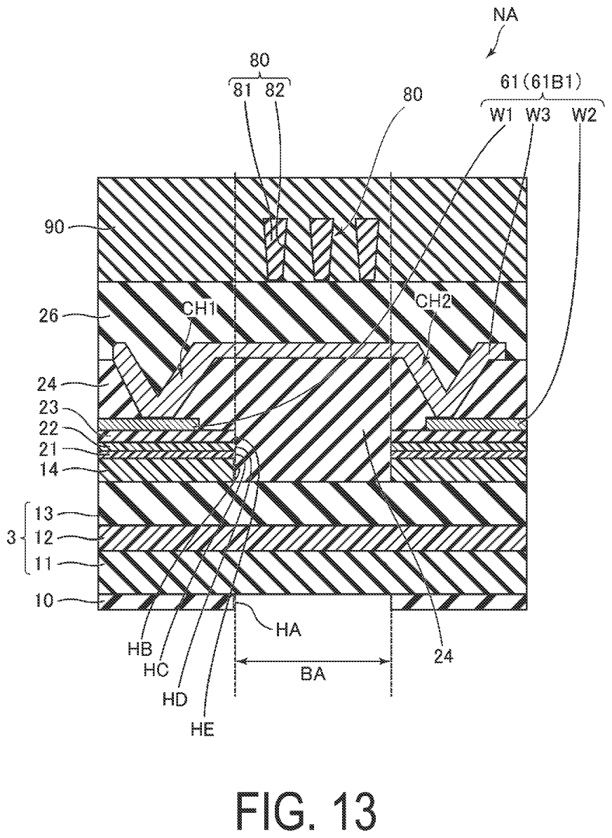

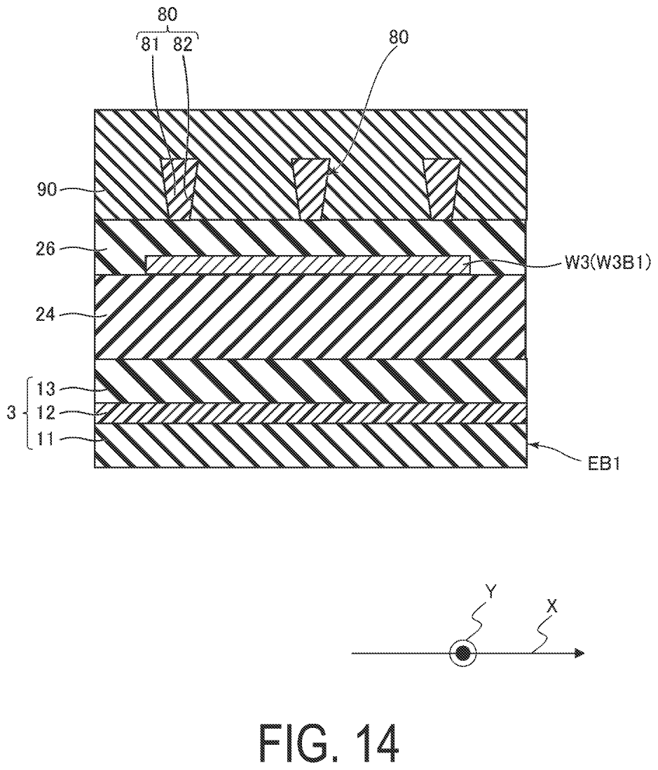

FIG. 13 is a cross-sectional view obtained by taking the lead-out wiring line 61B1 at one end near the bending region BA according to the second embodiment along the Y direction. FIG. 14 is a cross-sectional view obtained by taking the relay wiring line W3B1 at one end of the bending region BA according to the second embodiment along the X direction.

In the second embodiment, for example, among the lead-out wiring lines 61, the first lead-out wiring line W1 and the second lead-out wiring line W2 are provided at the same layer as that of the source electrode SE and the drain electrode DE, and the relay wiring line W3 is provided at the same layer as that of the intermediate electrode M4.

The relay wiring line W3 is electrically connected at one end portion thereof to the end portion of the first lead-out wiring line W1 through the first contact hole CH1 formed in the first flattening layer (first insulating layer) 24 covering the first lead-out wiring line W1. Additionally, the relay wiring line W3 is electrically connected at the other end portion thereof to the end portion of the second lead-out wiring line W2 through the second contact hole CH2 formed in the first flattening layer (first insulating layer) 24 covering the second lead-out wiring line W2.

In the frame region NA, the base material 3 (that is, the first base resin layer 11, the buffer layer 12, and the second base resin layer 13) provided on the second film 10 is provided, the base coat layer 14 is provided on the base material 3, the gate insulating layer 21 is provided on the base coat layer 14, the first inorganic insulating layer 22 is provided on the gate insulating layer 21, the second inorganic insulating layer 23 is provided on the first inorganic insulating layer 22, and the first lead-out wiring line W1 and the second lead-out wiring line W2 are provided on the second inorganic insulating layer 23. Furthermore, the first flattening layer 24 is provided so as to cover the first lead-out wiring line W1 and the second lead-out wiring line W2, the second flattening layer 26 is provided on the first flattening layer 24, and the plurality of protruding portions 81 that constitute the anchor portions 80 and that are provided at the same layer as that of the bank 25 on the second flattening layer 26 are provided. Additionally, the reinforcing layer 90 that covers the plurality of protruding portions 81 and that is provided with the plurality of recessed portions 82 constituting the anchor portions 80 is provided on the second flattening layer 26. Furthermore, in the bending region BA, the first flattening layer 24 where the plurality of relay wiring lines W3 are layered at a surface thereof is provided.

In the base coat layer (second insulating layer) 14 provided at the lower layer of the first lead-out wiring line W1 and the second lead-out wiring line W2, the opening HB is formed in a region overlapping the bending region BA. In the gate insulating layer (second insulating layer) 21 provided at the lower layer of the first lead-out wiring line W1 and the second lead-out wiring line W2, the opening HC is formed in the region overlapping the bending region BA. The opening HD is formed in the region overlapping the bending region BA in the first inorganic insulating layer (second insulating layer) 22 provided at the lower layer of the first lead-out wiring line W1 and the second lead-out wiring line W2. In the second inorganic insulating layer (second insulating layer) 23 provided at the lower layer of the first lead-out wiring line W1 and the second lead-out wiring line W2, the opening HE is formed in the region overlapping the bending region BA.

In the bending region BA, the first flattening layer 24 is provided in a region surrounded by the surface of the second base resin layer 13 exposed in the bending region BA, the opening HB formed in the base coat layer 14, the opening HC formed in the gate insulating layer 21, the opening HD formed in the first inorganic insulating layer 22, and the opening HE formed in the second inorganic insulating layer 23. The first flattening layer 24 in the bending region BA continuously extends in the X direction so as to connect both the end portions EB1 and EB2 to each other. The relay wiring line W3 extending in the Y direction is provided on the first flattening layer 24 in the bending region BA.

Note that the first flattening layer 24 provided in the bending region BA and the first flattening layer 24 provided in the display region DA are separated without being connected.

The second flattening layer 26 is provided on the first flattening layer 24 so as to cover the relay wiring line W3 provided at the same layer as that of the intermediate electrode M4. Note that the second flattening layer 26 provided in the display region DA does not need to be connected to the second flattening layer 26 provided near the bending region BA.

As illustrated in FIG. 12 and FIG. 13, the display panel 2 according to the present embodiment includes the first flattening layer (first resin layer) 24, the plurality of relay wiring lines W3 that are provided on the first flattening layer 24 and that electrically connect the display region DA and the terminal region TA, the second flattening layer (second resin layer) 26 provided at the upper layer of the plurality of relay wiring lines W3 and the first flattening layer 24, and the reinforcing layer (third resin layer) 90 provided on the second flattening layer 26 in the bending region BA. Then, surfaces of the second flattening layer (second resin layer) 26 and the reinforcing layer 90 (third resin layer) are provided with the plurality of anchor portions 80 each of which includes the protruding portion 81 provided at one surface and the recessed portion 82 provided at the other surface, the recessed portion 82 being inserted with the protruding portion 81.

Thereby, when the bending region BA is bent, the plurality of anchor portions 80 exhibit a so-called anchoring effect, and the plurality of protruding portions 81 and the plurality of recessed portions 82 are difficult to peel off from each other. That is, even when the bending region BA is bent, the second flattening layer 26 and the reinforcing layer 90 that are provided with the plurality of anchor portions 80 can be difficult to peel off from each other. This makes it possible to suppress cracks of the second flattening layer 26 and the reinforcing layer 90, and disconnection of the plurality of relay wiring lines W3 provided in the bending region BA due to the cracks.

Note that the cross-sectional shape and the arrangement pattern of the plurality of anchor portions 80 may change in various ways as described in the first embodiment.

For example, in FIG. 13 and FIG. 14, the example is illustrated in which the plurality of protruding portions 81, among the plurality of anchor portions 80, are provided at the surface (one surface) of the second flattening layer 26. Additionally, the example is illustrated in which the plurality of recessed portions 82, among the plurality of anchor portions 80, are provided at the surface (other surface) of the reinforcing layer 90.

Alternatively, for example, the plurality of protruding portions 81 may be provided at the surface (one surface) of the reinforcing layer 90, and the plurality of recessed portions 82 may be provided at the surface of the second flattening layer 26 (the other surface).

The elements described in the above-described embodiments and the modified examples may be appropriately combined in a range in which a contradiction does not arise.

### REFERENCE SIGNS LIST

1 Display device
2 Display panel
3 Base material
4 TFT layer
5 Light-emitting element
6 Sealing layer
7 First film
10 Second film
11 First base resin layer
12 Buffer layer
13 Second base resin layer
14 Base coat layer (second insulating layer)
20 Semiconductor layer
21 Gate insulating layer (second insulating layer)
22 First inorganic insulating layer (first insulating layer, second insulating layer)
23 Second inorganic insulating layer (first insulating layer, second insulating layer)
24 First flattening layer (first insulating layer, first resin layer, second resin layer)
25 Bank
26 Second flattening layer (second resin layer)
60 Terminal
61 Lead-out wiring line
65 Filling layer (first resin layer)
80 Anchor portion
81 Protruding portion
82 Recessed portion
BA Bending region
CH1 First contact hole
CH2 Second contact hole
DA Display region
DE Drain electrode
EB1 to EB4 End portions
GE Gate electrode
GW Gate wiring line
HA to HE Opening
M4 Intermediate electrode
NA Frame region
SE Source electrode
SL Slit
SP Subpixel
TA Terminal region
W1 First lead-out wiring line
W2 Second lead-out wiring line
W3 Relay wiring line

1. A display device comprising:
a display region of an image;
a terminal region provided with a plurality of terminals; and
a bending region being a region between the display region and the terminal region and being bendable,
wherein the bending region includes
a first resin layer,
a plurality of relay wiring lines provided on the first resin layer and provided between the display region and the terminal region,
a second resin layer provided at an upper layer of the plurality of relay wiring lines and the first resin layer, and
a third resin layer provided on the second resin layer, and
a surface of each of the second resin layer and the third resin layer is provided with a plurality of anchor portions each of which includes a protruding portion provided at one surface and a recessed portion provided at the other surface, the recessed portion being engaged with the protruding portion.

2. The display device according to claim 1,
wherein the plurality of anchor portions are provided in a matrix shape in the bending region in a plan view.

3. The display device according to claim 2,
wherein the plurality of anchor portions are also provided outside the bending region.

4. The display device according to claim 1,
wherein each of a plurality of the protruding portions has a reversely tapered shape in which a length in a width direction parallel to the one surface increases from a base portion coming into contact with the one surface to a tip portion being an end portion at an opposite side to the base portion.

5. The display device according to claim 1,
wherein the plurality of anchor portions are provided at inner sides than the relay wiring lines provided at both ends among the plurality of relay wiring lines in a plan view.

6. The display device according to claim 1,
wherein the one surface provided with a plurality of the protruding portions is a surface of the second resin layer, and
the other surface provided with a plurality of the recessed portions is a surface of the third resin layer.

7. The display device according to claim 1,
wherein the one surface provided with a plurality of the protruding portions is a surface of the third resin layer, and
the other surface provided with a plurality of the recessed portions is a surface of the second resin layer.

8. The display device according to claim 7,
wherein each of the plurality of recessed portions has a depth extending through the second resin layer and the first resin layer.

9. The display device according to claim 1, further comprising:
a plurality of first lead-out wiring lines extending from the display region into a direction of the bending region;
a plurality of second lead-out wiring lines individually extending in the direction of the bending region from the corresponding plurality of terminals; and
a first insulating layer covering the plurality of first lead-out wiring lines and the plurality of second lead-out wiring lines,
wherein, in each of the plurality of relay wiring lines,
one end portion is electrically connected to the corresponding first lead-out wiring line among the plurality of first lead-out wiring lines through a corresponding first contact hole among a plurality of the first contact holes formed in the first insulating layer, and
the other end portion is electrically connected to the corresponding second lead-out wiring line among the plurality of second lead-out wiring lines through a corresponding second contact hole among a plurality of the second contact holes formed in the first insulating layer.

10. The display device according to claim 9, further comprising:
a second insulating layer provided at a lower layer of the plurality of first lead-out wiring lines and the plurality of second lead-out wiring lines,
wherein, in the bending region, the second insulating layer includes an opening extending in a direction intersecting the plurality of relay wiring lines.

11. The display device according to claim 9,
wherein the display region includes a plurality of thin film transistors each including a gate electrode, and a source electrode and a drain electrode that are provided at a layer different from a layer of the gate electrode,
the plurality of first lead-out wiring lines and the plurality of second lead-out wiring lines are provided at a layer identical to a layer of a plurality of the gate electrodes, and
the plurality of relay wiring lines are provided at a layer identical to a layer of a plurality of the source electrodes and a plurality of the drain electrodes.

12. The display device according to claim 9,
wherein the display region includes
a plurality of thin film transistors each including a gate electrode, and a source electrode and a drain electrode that are provided at a layer different from a layer of the gate electrode,
a first flattening layer covering the plurality of thin film transistors and including a resin material,
an intermediate electrode provided in an island shape on the first flattening layer and configured to be electrically connected to the drain electrode through a contact hole formed in the first flattening layer,
a second flattening layer covering the intermediate electrode, provided on the first flattening layer, and including a resin material, and
an anode electrode or a cathode electrode provided in an island shape on the second flattening layer,
the plurality of first lead-out wiring lines and the plurality of second lead-out wiring lines are provided at a layer identical to a layer of a plurality of the source electrodes and a plurality of the drain electrode, and
the plurality of relay wiring lines are provided at a layer identical to a layer of the intermediate electrode.

13. A manufacturing method of a display device including
a display region of an image,
a terminal region provided with a plurality of terminals, and
a bending region being a region between the display region and the terminal region and being bendable,
the manufacturing method comprising:
forming the bending region,
wherein the forming of the bending region includes
forming a first resin layer,
forming a plurality of relay wiring lines between the display region and the terminal region on the first resin layer,
forming a second resin layer at an upper layer of the plurality of relay wiring lines and the first resin layer,
forming a plurality of protruding portions or a plurality of recessed portions at a surface of the second resin layer, and
forming a third resin layer on the second resin layer, and
the forming of the third resin layer includes forming a plurality of anchor portions by forming a plurality of recessed portions engaged with the plurality of protruding portions, or the plurality of protruding portions engaged with the plurality of recessed portions.

14. The manufacturing method of the display device according to claim 13, wherein the third resin layer includes ultraviolet-curing resin.

15. The manufacturing method of the display device according to claim 13, further comprising:
forming the plurality of protruding portions on the second resin layer before forming the third resin layer, in the bending region,
wherein the forming of the third resin layer includes forming the plurality of anchor portions by forming the plurality of recessed portions engaged with the plurality of protruding portions at the third resin layer.

16. The manufacturing method of the display device according to claim 13, further comprising:
bending the bending region after forming the plurality of anchor portions.
